(19) United States
(12) Patent Application Publication
(10) Pub. No.: US 2023/0282662 A1
(43) Pub. Date: Sep. 7, 2023

(54) IMAGE SENSOR

(71) Applicant: Samsung Electronics Co., Ltd., Suwon-si (KR)

(72) Inventors: KWANGHEE LEE, Seongnam-si (KR); JAE HO KIM, Seoul (KR); UIHUI KWON, Hwaseong-si (KR); EUIYOUNG SONG, Seoul (KR)

(21) Appl. No.: 18/088,362

(22) Filed: Dec. 23, 2022

(30) Foreign Application Priority Data
Mar. 4, 2022 (KR) 10-2022-0027904

(51) Int. Cl. H01L 27/146

(52) U.S. Cl. CPC H01L 27/14625; H01L 27/14645; H01L 27/14621; H01L 27/14623; H01L 27/14627; H01L 27/1463; H01L 27/14685

(57) ABSTRACT

An image sensor comprising a substrate having first and second surfaces opposite to each other, a pixel isolation section that penetrates the substrate and separates a plurality of pixels constituting first, second, and third pixel groups, each of the first, second, and third pixel groups including pixels that are arranged in n columns and m rows, a light-shield grid on the first surface and overlapping the pixel isolation section, and a light modulator on the first surface and overlapping the pixel isolation section on a center of each of the first, second, and third pixel groups. The light-shield grid has a first width in a first direction. The light modulator has a second width greater than the first width in the first direction.

### CROSS-REFERENCE TO RELATED APPLICATION

This U.S. nonprovisional application claims priority under 35 U.S.C § 119 to Korean Patent Application No. 10-2022-0027904 filed on Mar. 4, 2022 in the Korean Intellectual Property Office, the disclosure of which is hereby incorporated by reference in its entirety.

### BACKGROUND

The present inventive concepts relate to an image sensor.

An image sensor is a semiconductor device to transforms optical images into electrical signals. The image sensor may be classified into a charge coupled device (CCD) type and a complementary metal oxide semiconductor (CMOS) type. The CIS (CMOS image sensor) is a short for the CMOS type image sensor. The CIS may include a plurality of pixels that are two-dimensionally arranged. Each of the pixels includes a photodiode. The photodiode serves to transform incident light rays into electrical signals.

### SUMMARY

Some embodiments of the present inventive concepts provide an image sensor capable of achieving sharp images.

The object of the present inventive concepts is not limited to the mentioned above, and other objects which have not been mentioned above will be clearly understood to those skilled in the art from the following description.

According to some embodiments of the present inventive concepts, an image sensor includes a substrate having a first surface and a second surface that are opposite to each other, a plurality of pixels disposed at the substrate and grouped into a plurality of first pixel groups, a plurality of second pixel groups, and a plurality of third pixel groups, each pixel group of the plurality of first to third pixel groups including a first number of pixels arranged in n columns and m rows, n and m representing a number of columns in each pixel group and a number of row therein, respectively, and being integers equal to or greater than 2, a pixel isolation structure penetrating the substrate and including an inter-pixel group isolation and an intra-pixel group isolation, the inter-pixel group isolation separating two adjacent different pixel groups among the plurality of first to third pixel groups from each other, and the intra-pixel group isolation separating two adjacent pixels among the first number of pixels in each pixel group from each other, a light-shield grid on the first surface and overlapping the inter-pixel group isolation of the pixel isolation structure, and a light modulator on the first surface and overlapping the intra-pixel group isolation of the pixel isolation structure at a center of each pixel group of the plurality of first to third pixel groups. The light-shield grid has a first width in a first direction, and the light modulator has a second width, in the first direction, greater than the first width in the first direction.

According to some embodiments of the present inventive concepts, an image sensor includes a substrate having a first surface and a second surface that are opposite to each other, a plurality of pixels disposed at the substrate and grouped into a plurality of first pixel groups, a plurality of second pixel groups, and a plurality of third pixel groups, wherein each pixel group of the plurality of first to third pixel groups includes a first number of pixels arranged in n columns and m rows, n and m representing a number of columns in each pixel group and a number of row therein, respectively, and being integers equal to or greater than 2, a pixel isolation structure that penetrates the substrate and includes a polysilicon pattern and a dielectric layer that surrounds the polysilicon pattern, the pixel isolation structure including an inter-pixel group isolation and an intra-pixel group isolation, the inter-pixel group isolation separating two adjacent different pixel groups among the plurality of first to third pixel groups from each other, and the intra-pixel group isolation separating two adjacent pixels among the first number of pixels in each pixel group from each other, a transfer gate on the second surface, a floating diffusion region adjacent to the second surface and on a side of the transfer gate, a light-shield grid on the first surface and overlapping the inter-pixel group isolation of the pixel isolation structure, a light modulator on the first surface and overlapping the intra-pixel group isolation of the pixel isolation structure at a center of each pixel group of the plurality of first to third pixel groups, a color filter between the light modulator and the light-shield grid, and a microlens on a region where the color filter, the light-shield grid, and the light modulator are disposed. The light-shield grid has a first width in a first direction, and the light modulator has a second width, in the first direction, greater than the first width in the first direction. A distance between a top end of the light modulator and a top end of the microlens is between about ⅓ a curvature radius of the microlens and about ⅔ of the curvature radius of the microlens.

According to some embodiments of the present inventive concepts, an image sensor includes a substrate having a first surface and a second surface that are opposite to each other, a plurality of pixels disposed at the substrate and grouped into a plurality of first pixel groups, a plurality of second pixel groups, and a plurality of third pixel groups, each pixel group of the plurality of first to third pixel groups including a first number of pixels arranged in n columns and m rows, n and m representing a number of columns in each pixel group and a number of row therein, respectively, and being integers equal to or greater than 2, a pixel isolation structure that penetrates the substrate and separates the plurality of pixels from each other, the pixel isolation structure having a lattice shape when viewed in a plan view, a light-shield grid on the first surface and overlapping the pixel isolation structure, and a light modulator on the first surface and overlapping the pixel isolation structure at a center of each pixel group of the plurality of first to third pixel groups. The light-shield grid has a first width in a first direction, and the light modulator has a second width, in the first direction, greater than the first width in the first direction. The light-shield grid has a first light-shield pattern and a first low-refractive pattern that are sequentially stacked, and the light modulator has a second light-shield pattern and a second low-refractive pattern that are sequentially stacked. The first light-shield pattern and the second light-shield pattern include the same material, and the first low-refractive pattern and the second low-refractive pattern include the same dielectric material.

### BRIEF DESCRIPTION OF THE DRAWINGS

FIG. 1 illustrates a block diagram showing an image sensor according to some embodiments of the present inventive concepts.

FIG. 2 illustrates a circuit diagram showing an active pixel sensor array of an image sensor according to some embodiments of the present inventive concepts.

FIG. 3A illustrates a plan view showing an image sensor according to some embodiments of the present inventive concepts.

FIG. 3B illustrates a plan view of one pixel group of an image sensor according to some embodiments of the present inventive concepts.

FIG. 4A illustrates a cross-sectional view taken along line A-A′ of FIG. 3A according to some embodiments of the present inventive concepts.

FIG. 4B illustrates a cross-sectional view showing an optical path in the image sensor of FIG. 4A.

FIGS. 5A and 5B illustrate cross-sectional views showing a method of fabricating an image sensor having the cross section of FIG. 4A.

FIGS. 6A to 6D illustrate plan views partially showing an image sensor according to some embodiments of the present inventive concepts.

FIGS. 7A and 7B illustrate plan views showing an image sensor according to some embodiments of the present inventive concepts.

FIGS. 8A to 8E illustrate cross-sectional views taken along line A-A′ of FIG. 3A according to some embodiments of the present inventive concepts.

FIG. 9 illustrates a cross-sectional view showing an image sensor according to some embodiments of the present inventive concepts.

FIG. 10 illustrates a cross-sectional view taken along line A-A′ of FIG. 3A according to some embodiments of the present inventive concepts.

### DETAIL PARTED DESCRIPTION OF EMBODIMENTS

Some embodiments of the present inventive concepts will now be described in detail with reference to the accompanying drawings to aid in clearly explaining the present inventive concepts.

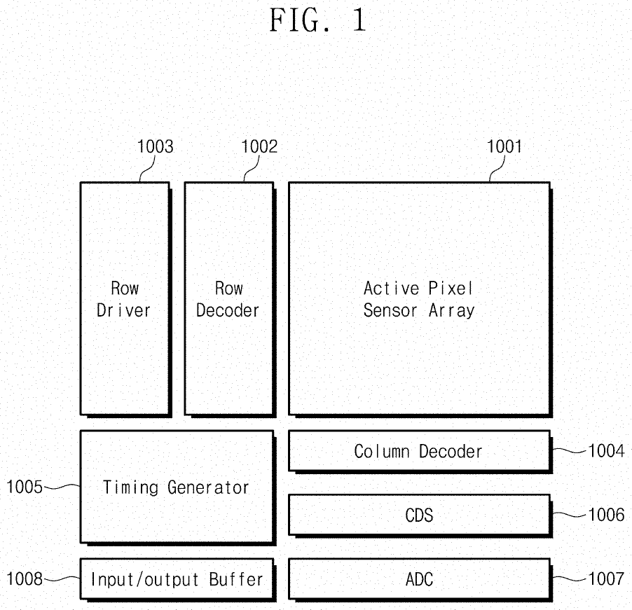

FIG. 1 illustrates a block diagram showing an image sensor according to some embodiments of the present inventive concepts.

Referring to FIG. 1, an image sensor may include an active pixel sensor array 1001, a row decoder 1002, a row driver 1003, a column decoder 1004, a timing generator 1005, a correlated double sampler (CDS) 1006, an analog-to-digital converter (ADC) 1007, and an input/output (I/O) buffer 1008.

The active pixel sensor array 1001 may include a plurality of unit pixels that are two-dimensionally arranged. Each unit pixel of the plurality of unit pixels may be configured to convert optical signals into electrical signals. The active pixel sensor array 1001 may be driven by a plurality of driving signals such as a pixel selection signal, a reset signal, and a charge transfer signal from the row driver 1003. The correlated double sampler 1006 may be provided with the converted electrical signals.

The row driver 1003 may provide the active pixel sensor array 1001 with several driving signals for driving several unit pixels in accordance with a decoded result obtained from the row decoder 1002. When the unit pixels are arranged in a matrix shape, the driving signals may be provided for respective rows.

The timing generator 1005 may provide timing and control signals to the row decoder 1002 and the column decoder 1004.

The correlated double sampler 1006 may receive the electrical signals generated from the active pixel sensor array 1001, and may hold and sample the received electrical signals. The correlated double sampler 1006 may perform a double sampling operation to sample a specific noise level and a signal level of the electrical signal, and then may output a difference level corresponding to a difference between the noise and signal levels.

The analog-to-digital converter 1007 may convert analog signals, which correspond to the difference level received from the correlated double sampler 1006, into digital signals, and then may output the converted digital signals.

The input/output buffer 1008 may latch the digital signals and then sequentially output the latched digital signals to an image signal processing unit (not shown) in response to the decoded result obtained from the column decoder 1004.

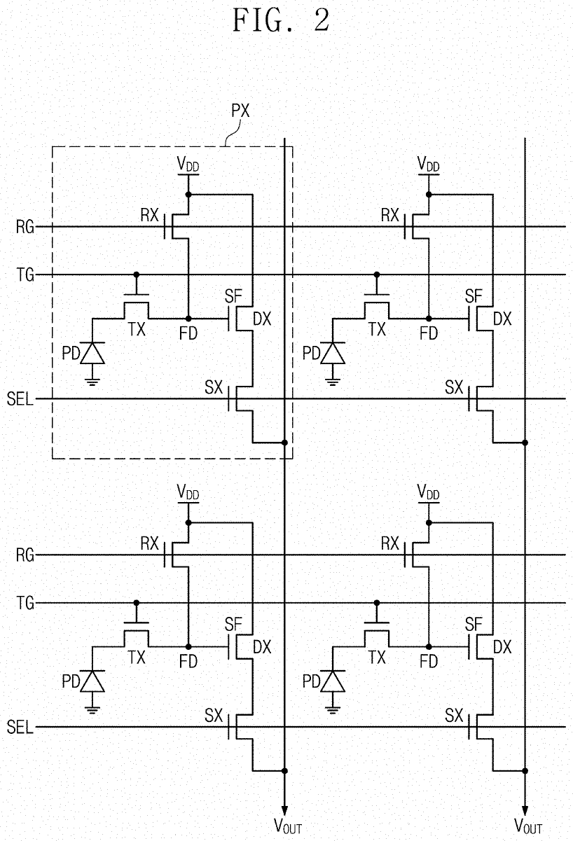

FIG. 2 illustrates a circuit diagram showing an active pixel sensor array of an image sensor according to some embodiments of the present inventive concepts.

Referring to FIGS. 1 and 2, the active pixel sensor array 1001 may include a plurality of pixels PX, which pixels PX may be arranged in a matrix shape. Each of the pixels PX may include a transfer transistor TX and logic transistors RX, SX, and DX. The logic transistors RX, SX, and DX may include a reset transistor RX, a selection transistor SX, and a source follower transistor DX. The transfer transistor TX may include a transfer gate TG. Each of the pixels PX may further include a photoelectric conversion element PD (i.e., a photoelectric diode or a photoelectric conversion region) and a floating diffusion region FD.

The photoelectric conversion element PD may create and accumulate photo-charges in proportion to an amount of externally incident light. The photoelectric conversion element PD may include a photodiode, phototransistor, a photo-gate, a pinned photodiode, or a combination thereof. The transfer transistor TX may transfer charges generated in the photoelectric conversion element PD into the floating diffusion region FD. The floating diffusion region FD may accumulate and store charges that are generated and transferred from the photoelectric conversion element PD. The source follower transistor DX may be controlled by an amount of photo-charges accumulated in the floating diffusion region FD.

The reset transistor RX may periodically reset the charges accumulated in the floating diffusion region FD. The reset transistor RX may have a drain electrode connected to the floating diffusion region FD and a source electrode connected to a power voltage VDD. When the reset transistor RX is turned on, the floating diffusion region FD may be supplied with the power voltage VDD connected to the source electrode of the reset transistor RX. Accordingly, when the reset transistor RX is turned on, the charges accumulated in the floating diffusion region FD may be exhausted or depleted from the floating diffusion region FD and thus the floating diffusion region FD may be reset.

The source follower transistor DX may serve as a source follower buffer amplifier. The source follower transistor DX may amplify a variation in electrical potential of the floating diffusion region FD and may output the amplified electrical potential to an output line VOUT.

The selection transistor SX may select each row of the pixels PX to be readout. When the selection transistor SX is turned on, the power voltage VDD may be applied to a drain electrode of the source follower transistor DX.

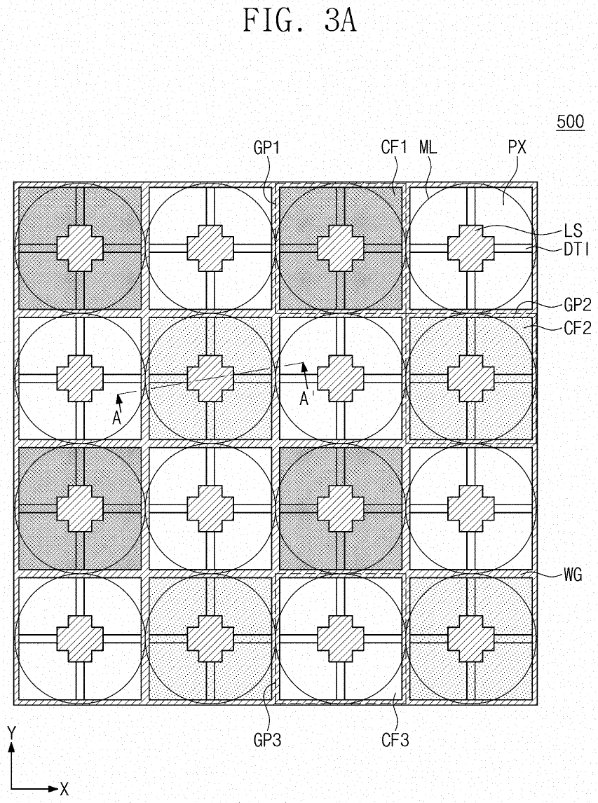

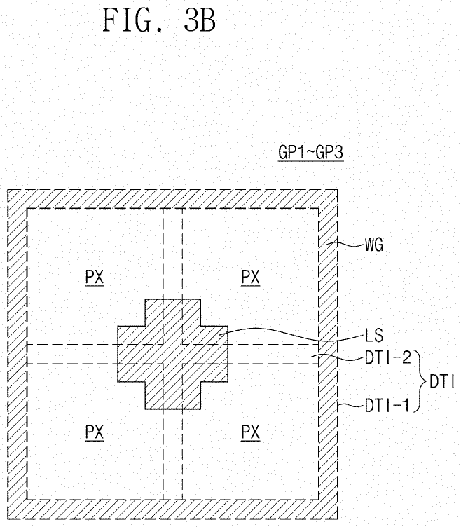

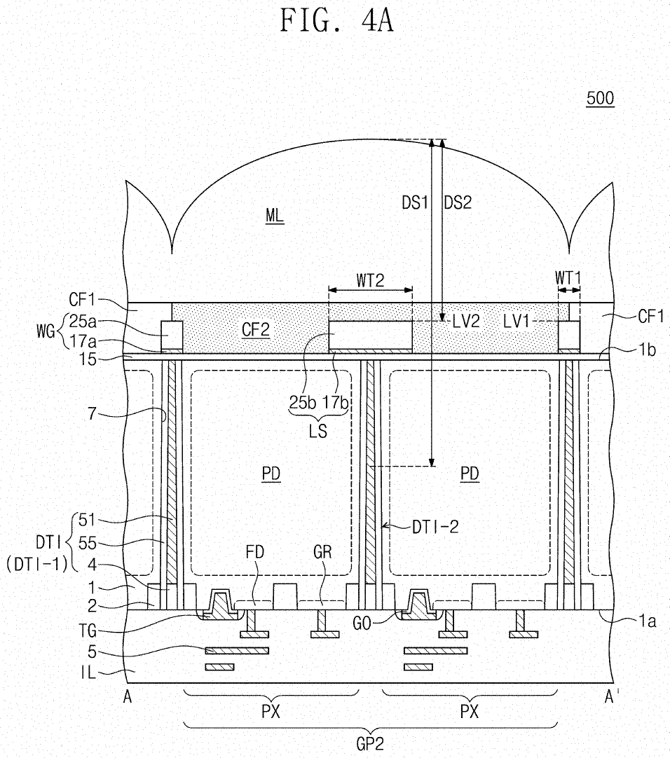

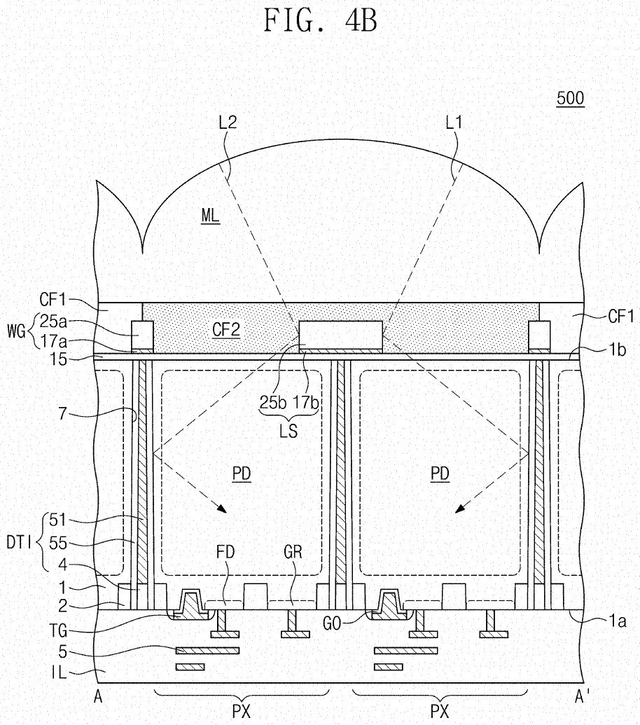

FIG. 3A illustrates a plan view showing an image sensor according to some embodiments of the present inventive concepts. FIG. 3B illustrates a plan view of one pixel group of an image sensor according to some embodiments of the present inventive concepts. FIG. 4A illustrates a cross-sectional view taken along line A-A′ of FIG. 3A according to some embodiments of the present inventive concepts. FIG. 4B illustrates a cross-sectional view showing an optical path in the image sensor of FIG. 4A.

Referring to FIGS. 3A, 3B, and 4A, an image sensor 500 according to the present embodiment may include a semiconductor substrate 1. The semiconductor substrate 1 may be a monocrystalline silicon wafer or an epitaxial silicon layer. The semiconductor substrate 1 may be doped with impurities having a first conductivity type. For example, the first conductivity type may be p-type, and the impurities may be boron. The semiconductor substrate 1 may have a first surface 1a and a second surface 1b that are opposite to each other.

A shallow device isolation section 2 (i.e., a shallow trench isolation) may be disposed adjacent to the first surface 1a of the semiconductor substrate 1. The shallow device isolation section 2 may define active regions for transistors disposed on the first surface 1a. The shallow device isolation section 2 may be formed by a shallow trench isolation (STI) process. The shallow device isolation section 2 may have a single-layered or multi-layered structure formed of at least one selected from a silicon oxide layer, a silicon nitride layer, and a silicon oxynitride layer.

A pixel isolation section DTI (i.e., a pixel isolation structure or a deep trench isolation) may be disposed in the semiconductor substrate 1, separating pixels PX from each other. The pixel isolation section DTI may be disposed in a deep trench 7. The deep trench 7 may be formed to extend from the first surface 1a toward the second surface 1b. The deep trench 7 may be formed to penetrate the shallow device isolation section 2 and the semiconductor substrate 1. The deep trench 7 may have a width that decreases in a direction from the first surface 1a toward the second surface 1b.

The pixel isolation section DTI may include an impurity-doped polysilicon pattern 51, a side dielectric layer 55 that surrounds a sidewall of the polysilicon pattern 51, and a buried dielectric pattern 4. The polysilicon pattern 51 may have a thermal expansion coefficient almost identical to that of the semiconductor substrate 1 formed of monocrystalline silicon, which may reduce a physical stress caused by a difference in thermal expansion coefficient of materials. The polysilicon pattern 51 may serve as a common bias line. The polysilicon pattern 51 may be supplied with a negative voltage. Thus, dark current characteristics may be improved due to holding of holes possibly present on a surface of the deep trench 7. The side dielectric layer 55 and the buried dielectric pattern 4 may independently have a single-single-layered or multi-layered structure formed of at least one selected from a silicon oxide layer, a silicon nitride layer, and a silicon oxynitride layer.

On each of the pixels PX, the first surface 1a may be provided thereon with the transfer transistor TX discussed with reference to FIG. 2. In addition, on each of the pixels PX, there may be disposed at least one of the logic transistors RX, SX, and DX. The logic transistors RX, SX, and DX may be shared by neighboring pixels PX. The transfer transistor TX may include a transfer gate TG, a gate dielectric layer GO, and a floating diffusion region FD disposed on a side of the transfer gate TG and the gate dielectric layer GO.

The transfer gate TG may have a vertical type shape in which a portion of the transfer gate TG is inserted into the semiconductor substrate 1. In an embodiment, the transfer gate TG may have a planar type shape. The gate dielectric layer GO may include at least one selected from, for example, a silicon oxide layer, a silicon nitride layer, and a high-k dielectric layer. The high-k dielectric layer may include a dielectric material whose dielectric constant is greater than that of silicon oxide. The transfer gate TG may include a conductive layer. The floating diffusion region FD may be doped with impurities having a second conductivity type opposite to or different from the first conductivity type. Although FIG. 4A depicts that the floating diffusion region FD is disposed on each of the pixels PX, the floating diffusion region FD may be shared by neighboring pixels PX. In this case, the floating diffusion region FD may be positioned between neighboring pixels PX or at a center of one of pixel groups GP1 to GP3 which will be discussed below.

On each of the pixels PX, the semiconductor substrate 1 may be provided therein with a ground region GR adjacent to the first surface 1a. The ground region GR may be doped with impurities having the first conductivity type that is the same as that of impurities doped in the semiconductor substrate 1, and may have an impurity concentration greater than that of the semiconductor substrate 1.

On each of the pixels PX, a photoelectric conversion element PD may be disposed in the semiconductor substrate 1. The photoelectric conversion element PD may be a region doped with impurities having the second conductivity type opposite to or different from the first conductivity type. For example, the photoelectric conversion element PD may be doped with n-type impurities such as arsenic and phosphorus. The photoelectric conversion element PD and the semiconductor substrate 1 therearound may form a p-n junction, thereby constituting a photodiode.

The first surface 1a of the semiconductor substrate 1 may be covered with an interlayer dielectric layer IL. The interlayer dielectric layer IL may have a single-layered or multi-layered structure formed of at least one selected from a silicon oxide layer, a silicon oxynitride layer, a silicon nitride layer, and a porous dielectric layer. The interlayer dielectric layer IL may be provided therein with multi-layered wiring lines 5.

As shown in FIG. 3A, the pixels PX may be two-dimensionally arranged along a first direction X and a second direction Y. Each of pixels groups GP1 to GP3 may include four neighboring pixels PX that are arranged in a 2×2 configuration constituted by two rows and two columns. The pixel groups GP1 to GP3 may be correspondingly covered with color filters CF1 to CF3 and a microlens ML. For example, a first pixel group GP1 including four pixels PX arranged in two rows and two columns may be covered with one first color filter CF1 and one microlens ML. A second pixel group GP2 including four pixels PX arranged in two rows and two columns may be covered with one second color filter CF2 and one microlens ML. A third pixel group GP3 including four pixels PX arranged in two rows and two columns may be covered with one third color filter CF3 and one microlens ML. Lower portions of the microlenses ML may be connected to each other. The color filters CF1 to CF3 may each have one of green, red, and blue colors. For example, the first color filter CF1 may have a red color, the second color filter CF2 may have a blue color, and the third color filter CF3 may have a green color.

The image sensor 500 may have an autofocus function achieved by allowing four pixels PX to detect light that passes through one microlens ML disposed on one of the pixel groups GP1 to GP3. In addition, the pixel isolation section DTI may separate four pixels PX included in one of the pixel groups GP1 to GP3 from each other. Such separation of the four pixels PX using the pixel isolation section DTI may prevent blooming between neighboring pixels PX from occurring. For example, the pixel isolation section DTI may serve to prevent excess charges generated in each pixel group from flowing into another pixel group. Therefore, the image sensor 500 may perform an excellent autofocus function and accomplish a sharp image. The image sensor 500 may be an autofocus image sensor. In the present embodiment, four pixels PX arranged in a 2×2 configuration may constitute one of the pixel groups GP1 to GP3, but the present inventive concepts are not limited thereto. For example, one of the pixel groups GP1 to GP3 may include the pixels PX arranged in an n×m configuration, where n and m may independently be a natural number equal to or greater than 2. In an embodiment, a plurality of pixels PX may be disposed at the substrate 1 and may be grouped into a plurality of first pixel groups GP1, a plurality of second pixel groups GP2, and a plurality of third pixel groups GP3. In an embodiment, each of the plurality of first pixel groups GP1 may emit a first color, each of the plurality of second pixel groups GP2 may emit a second color, and each of the plurality of third pixel groups GP3 may emit a third color. The first to third colors may be different from each other. Each pixel group of the plurality of first to third pixel groups GP1 to GP3 may include a first number of pixels (e.g., 4) arranged in n columns and m rows, where n and m represent a number of columns (e.g., 2) in each pixel group and a number of row therein (e.g., 2), respectively, and are integers equal to or greater than 2 The first number may be equal to a value of n times m. Each pixel group may include a corresponding color filter and a microlens. The pixel isolation section DTI may include an inter-pixel group isolation DTI-1 and an intra-pixel group isolation DTI-2. The inter-pixel group isolation DTI-1 may penetrate the substrate 1, separating two adjacent different pixel groups among the plurality of first to third pixel groups GP1 to GP3 from each other. Then intra-pixel group isolation DTI-2 may penetrate the substrate 1, separating two adjacent pixels among the first number of pixels arranged in each pixel group among the plurality of pixel groups GP1 to GP3 from each other. For example, the intra-pixel group isolation DTI-2 may separate two adjacent pixels among the four pixels in each pixel group from each other. In an embodiment, the intra-pixel group isolation DTI-2 may be connected to the inter-pixel isolation DTI-1 to form a lattice shape of the pixel isolation section DTI.

A fixed charge layer 15 may be interposed between the second surface 1b and the color filters CF1 to CF3. The fixed charge layer 15 may be in contact with the second surface 1b. The fixed charge layer 15 may have a negative fixed charge. The fixed charge layer 15 may be formed of one of metal oxide and metal fluoride that include at least one metal selected from hafnium (Hf), zirconium (Zr), aluminum (Al), tantalum (Ta), titanium (Ti), yttrium (Y), and lanthanides. For example, the fixed charge layer 15 may be a hafnium oxide layer or an aluminum oxide layer. In this case, hole accumulation may occur around the fixed charge layer 15. Therefore, dark current and white spot may be effectively reduced. The term “contact,” as used herein, refers to a direct connection (i.e., touching) unless the context indicates otherwise.

Although not shown, one or more of an antireflection layer and a planarization layer may be additionally disposed between the fixed charge layer 15 and the color filters CF1 to CF3. The antireflection layer may include, for example, silicon oxide or silicon nitride. The planarization layer may include silicon oxide.

A light-shield grid WG may be disposed on the fixed charge layer 15. The light-shield grid WG may overlap the pixel isolation section DTI positioned between the pixel groups GP1 to GP3. At a center of each of the pixel groups GP1 to GP3, the fixed charge layer 15 may be provided thereon with a light modulator LS that overlaps the pixel isolation section DTI. The light modulator LS may be spaced apart from the light-shield grid WG.

The light modulator LS may overlap a center of the microlens ML that overlies the light modulator LS. For example, a center of the light modulator LS may overlap the center of the microlens ML that overlies the light modulator LS. The light modulator LS may be covered with a corresponding one of the color filters CF1 to CF3. The light-shield grid WG may be covered with neighboring color filters CF1 to CF3.

The light-shield grid WG may include a first light-shield pattern 17a and a first low-refractive pattern 25a that are sequentially stacked. The light modulator LS may include a second light-shield pattern 17b and a second low-refractive pattern 25b that are sequentially stacked. The first light-shield pattern 17a and the second light-shield pattern 17b may have the same thickness and the same metal. For example, the first light-shield pattern 17a and the second light-shield pattern 17b may include titanium or tungsten. The first low-refractive pattern 25a and the second low-refractive pattern 25b may include the same dielectric material. The first low-refractive pattern 25a and the second low-refractive pattern 25b may have a refractive index less than that of the color filters CF1 to CF3. For example, the first low-refractive pattern 25a and the second low-refractive pattern 25b may have a refractive index which is equal to or less than about 1.3. Therefore, light rays L1 and L2 that are incident as shown in FIG. 4B may be refracted by the light modulator LS and may then enter the photoelectric conversion element PD of a corresponding pixel PX.

As shown in FIG. 4A, the light-shield grid WG may have a first width WT1. The light modulator LS may have a second width WT2 greater than the first width WT1. For example, the second width WT2 may be about two to four times the first width WT1. As shown in FIGS. 3A and 3B, the light modulator LS may have a cross shape when viewed in plan. The second width WT2 of the light modulator LS may be greater than a width of the pixel isolation section DTI. The light modulator LS may completely cover the pixel isolation section DTI positioned on the center of each of the pixel groups GP1 to GP3. The light modulator LS may have a rectangular or square shape when viewed in a cross-sectional view.

As shown in FIG. 4A, the light-shield grid WG may have a top surface at a first level LV1. The light modulator LS may have a top surface at a second level LV2. In the present embodiment, the second level LV2 may be the same as the first level LV1. The top surface of the light modulator LS may be positioned at, or around, a focal distance of the microlens ML. For example, a distance DS2 between a top end of the microlens ML and the top surface (i.e., a top end) of the light modulator LS may be between about ⅓ a curvature radius DS1 of the microlens ML and about ⅔ of the curvature radius DS1 of the microlens ML. As shown in FIG. 4B, the light rays L1 and L2 incident through the microlens ML may be scattered by the light modulator LS, and may then enter the photoelectric conversion element PD. Therefore, the light rays L1 and L2 may be prevented from being incident on the polysilicon pattern 51 positioned in the pixel isolation section DTI below the light modulator LS. Because polysilicon has characteristics to absorb light, optical loss may occur when light is incident on the polysilicon pattern 51, and thus there may be a reduction in quantum efficiency (incident photon to converted electron ratio). The quantum efficiency may refer to a number of electrons generated per an incident photon. In the present inventive concepts, the light modulator LS may improve the quantum efficiency. Accordingly, the image sensor 500 may increase in quantity of light, improve in photosensitivity, with the result that sharp images may be accomplished. Furthermore, an excellent autofocus function may be provided. Terms such as “about” or “approximately” may reflect amounts, sizes, orientations, or layouts that vary only in a small relative manner, and/or in a way that does not significantly alter the operation, functionality, or structure of certain elements. For example, a range from “about 0.1 to about 1” may encompass a range such as a 0%-5% deviation around 0.1 and a 0% to 5% deviation around 1, especially if such deviation maintains the same effect as the listed range.

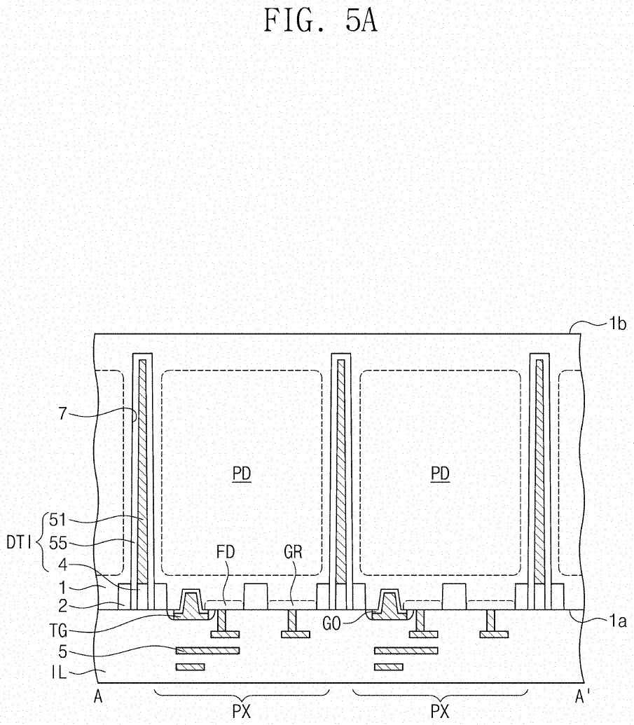

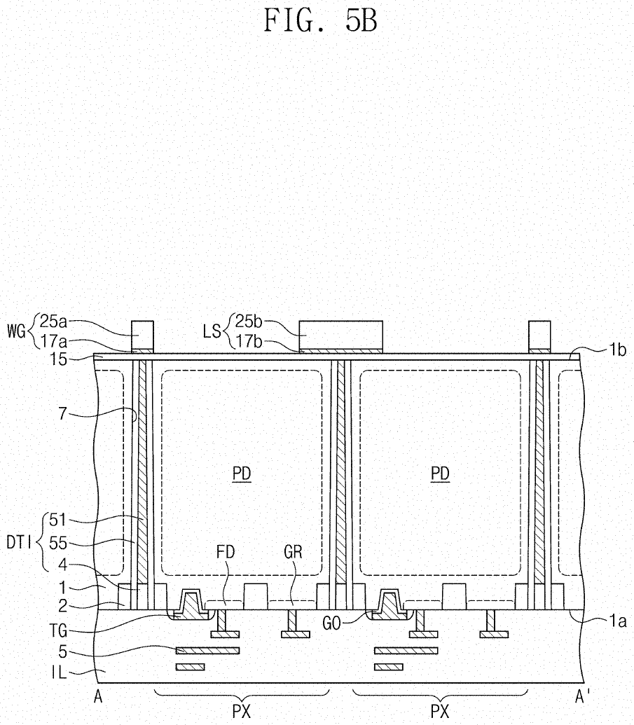

FIGS. 5A and 5B illustrate cross-sectional views showing a method of fabricating an image sensor having the cross section of FIG. 4A.

Referring to FIG. 5A, a semiconductor substrate 1 may be prepared which has a first surface 1a and a second surface 1b that are opposite to each other. In the semiconductor substrate 1, a shallow device isolation section 2 and a pixel isolation section DTI may be formed to define pixels PX. The pixel isolation section DTI may be formed to include an impurity-doped polysilicon pattern 51, a side dielectric layer 55 that surrounds a sidewall of the polysilicon pattern 51, and a buried dielectric pattern 4. The side dielectric layer 55 may be formed to cover a bottom surface of a deep trench 7. The side dielectric layer 55 may be formed to be spaced apart from the second surface 1b. On each of the pixels PX, a photoelectric conversion element PD may be formed in the semiconductor substrate 1. There may be formed, on the first surface 1a, a transfer gate TG, a gate dielectric layer GO, a floating diffusion region FD, and a ground region GR. The floating diffusion region FD and the ground region GR may be disposed on a side of the transfer gate TG and the gate dielectric layer GO. On the first surface 1a, multi-layered wiring lines 5 and an interlayer dielectric layer IL may be formed. The semiconductor substrate 1 may be turned upside down to cause the second surface 1b to face upwardly.

Referring to FIG. 5B, the second surface 1b of the semiconductor substrate 1 may undergo a back grinding process to partially remove the semiconductor substrate 1 and the side dielectric layer 55 and to expose the polysilicon pattern 51 of the pixel isolation section DTI. A fixed charge layer 15 may be formed on the second surface 1b of the semiconductor substrate 1. A light-shield layer and a low-refractive layer may be sequentially stacked on the fixed charge layer 15, and then the light-shield layer and the low-refractive layer may be sequentially etched to form a light-shield grid WG and a light modulator LS and to expose the fixed charge layer 15. The light-shield grid WG may include a first light-shield pattern 17a and a first low-refractive pattern 25a that are sequentially stacked. The light modulator LS may include a second light-shield pattern 17b and a second low-refractive pattern 25b that are sequentially stacked. At a center of each of pixel groups GP1 to GP3, the light modulator LS may be formed to overlap the pixel isolation section DTI. As shown in FIG. 3A, the light modulator LS may be formed to have a cross shape when viewed in a plan view.

In the present inventive concepts, the light modulator LS and the light-shield grid WG may be formed at the same time. Therefore, no process may be separately required to form the light modulator LS, and accordingly fabrication process may become simplified.

Subsequently, referring to FIGS. 3A and 4A, color filters CF1 to CF3 may be formed on the fixed charge layer 15. One of the color filters CF1 to CF3 may be formed to cover a corresponding one of the pixel groups GP1 to GP3. The color filters CF1 to CF3 may cover the light-shield grid WG and the light modulator LS. A microlens ML may be formed on each of the color filters CF1 to CF3.

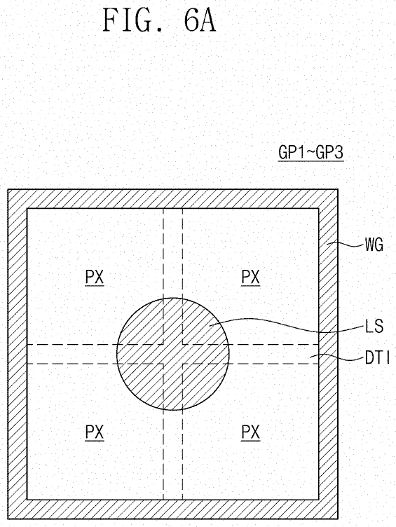

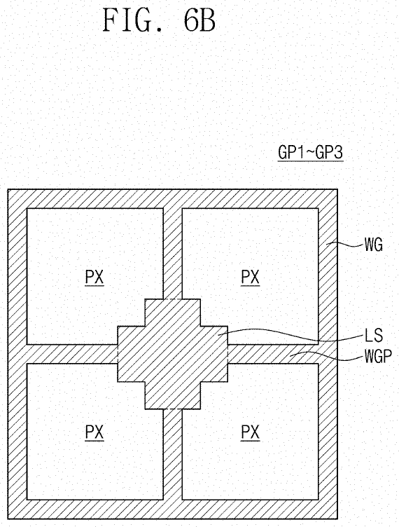

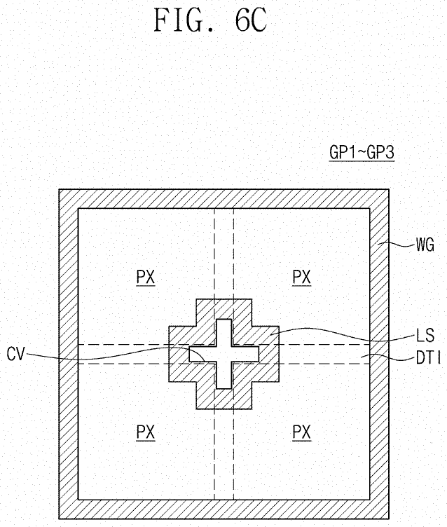

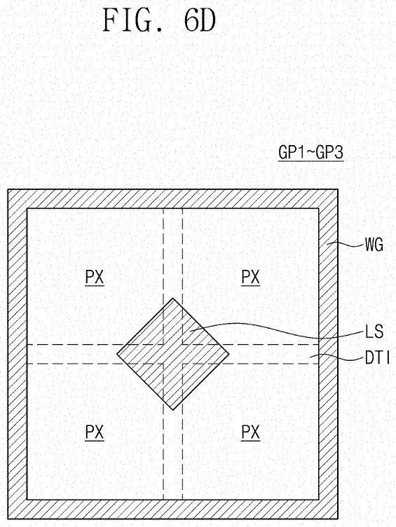

FIGS. 6A to 6D illustrate plan views partially showing an image sensor according to some embodiments of the present inventive concepts.

Referring to FIG. 6A, the light modulator LS according to the present embodiment may have a circular shape when viewed in a plan view. The light modulator LS may be spaced apart from the light-shield grid WG, and the pixel isolation section DTI may be exposed between the light modulator LS and the light-shield grid WG.

Referring to FIG. 6B, the light modulator LS may have a cross shape when viewed in a plan view. The light modulator LS may be connected through a grid protrusion WGP to the light-shield grid WG. The grid protrusion WGP may overlap the pixel isolation section DTI. In this case, the pixel isolation section DTI may not be exposed between the light modulator LS and the light-shield grid WG. The light modulator LS, the grid protrusion WGP, and the light-shield grid WG may be integrally connected into a single unitary body, and no boundary region may be present therebetween.

Referring to FIG. 6C, the light modulator LS may have a cross shape when viewed in a plan view. The light modulator LS may have an empty space CV (i.e., a through-hole) therein. The empty space CV may overlap a center of one of the pixel groups GP1 to GP3. The light modulator LS may be spaced apart from the light-shield grid WG, and the pixel isolation section DTI may be exposed between the light modulator LS and the light-shield grid WG. In an embodiment, a portion of the pixel isolation section DT1 disposed at a center of the one of the pixel groups GP1 to GP3 may be exposed by the empty space CV.

Referring to FIG. 6D, when viewed in a plan view, the light modulator LS may have a tetragonal shape, a pyramid shape, or a rhombic shape. The light modulator LS may be spaced apart from the light-shield grid WG, and the pixel isolation section DTI may be exposed between the light modulator LS and the light-shield grid WG.

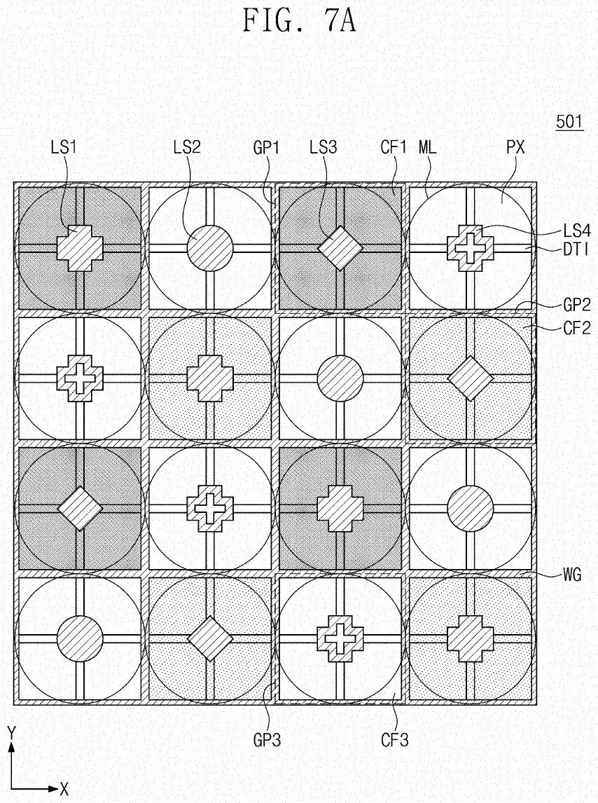

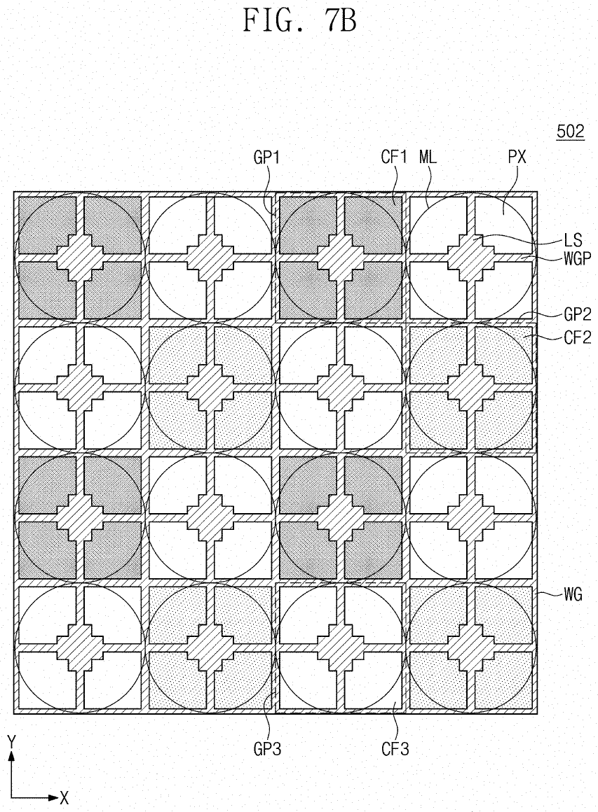

FIGS. 7A and 7B illustrate plan views showing an image sensor according to some embodiments of the present inventive concepts.

Referring to FIG. 7A, an image sensor 501 according to the present embodiment may include various shaped light modulators LS1 to LS4. Each of the light modulators LS1 to LS4 may be spaced apart from the light-shield grid WG. For example, a first light modulator LS1 having the cross shape as shown in FIG. 3B may be disposed at a center of the first pixel group GP1 located at an uppermost and first position from the left side in FIG. 7A. A second light modulator LS2 having the circular shape as shown in FIG. 6A may be disposed at a center of the third pixel group GP3 located at an uppermost and second position from the left side in FIG. 7A. A third light modulator LS3 having the rhombic shape as shown in FIG. 6D may be disposed at a center of the first pixel group GP1 located at an uppermost and third position from the left side in FIG. 7A. A fourth light modulator LS4 having the cross shape with the empty space CV therein as shown in FIG. 6C may be disposed at a center of the third pixel group GP3 located at an uppermost and fourth position from the left side in FIG. 7A. The first to fourth light modulator LS1 to LS4 may have their positions that are changed for each row or each column.

Referring to FIG. 7B, an image sensor 502 according to the present embodiment may be configured such that the light modulators LS are connected through the grid protrusions WGP to the light-shield grid WG. The image sensor 502 of FIG. 7A may have a shape where a plurality of pixel groups GP1 to GP3 as shown in FIG. 6B are arranged two-dimensionally.

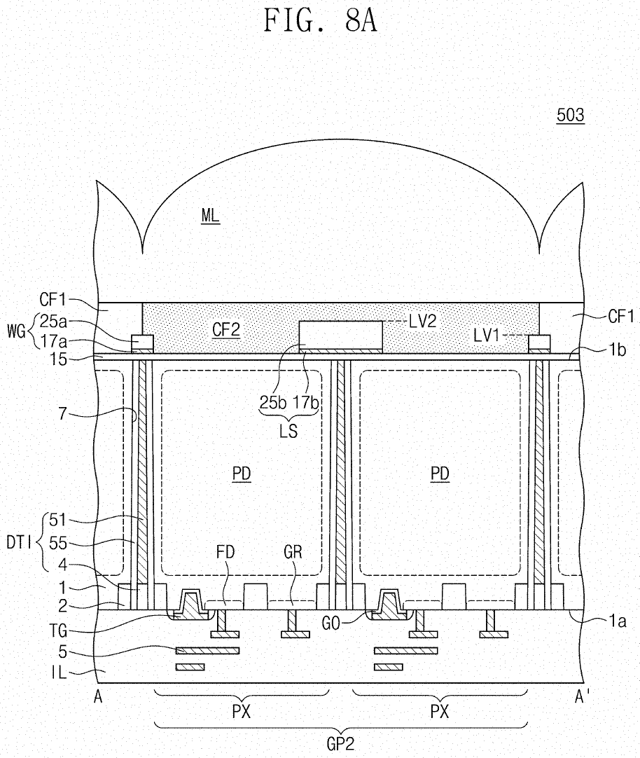

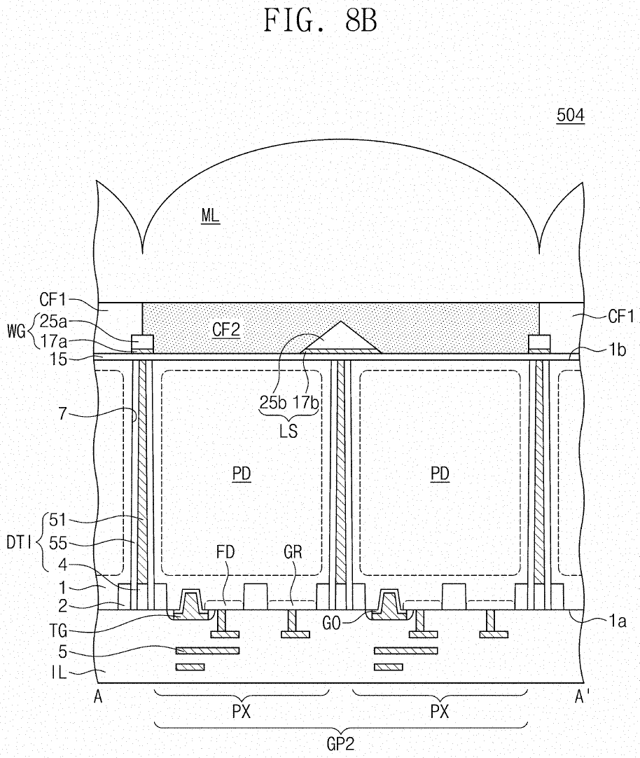

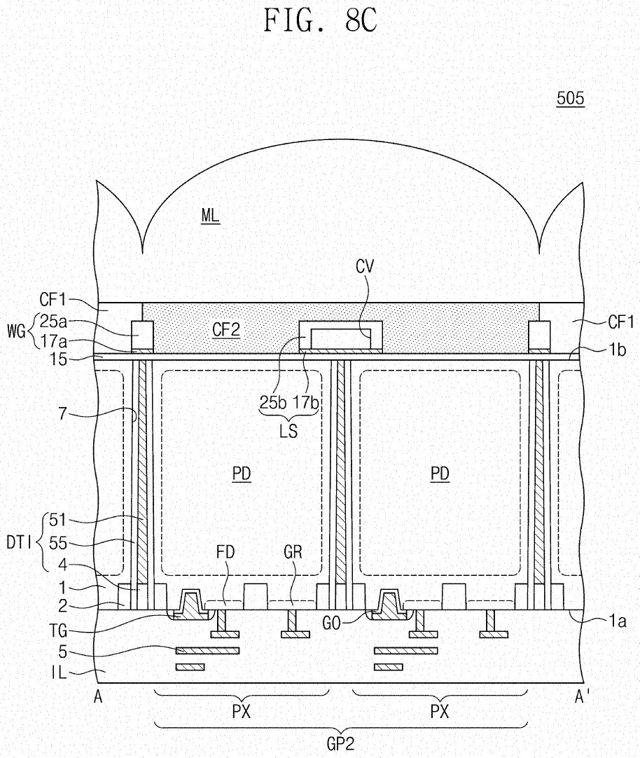

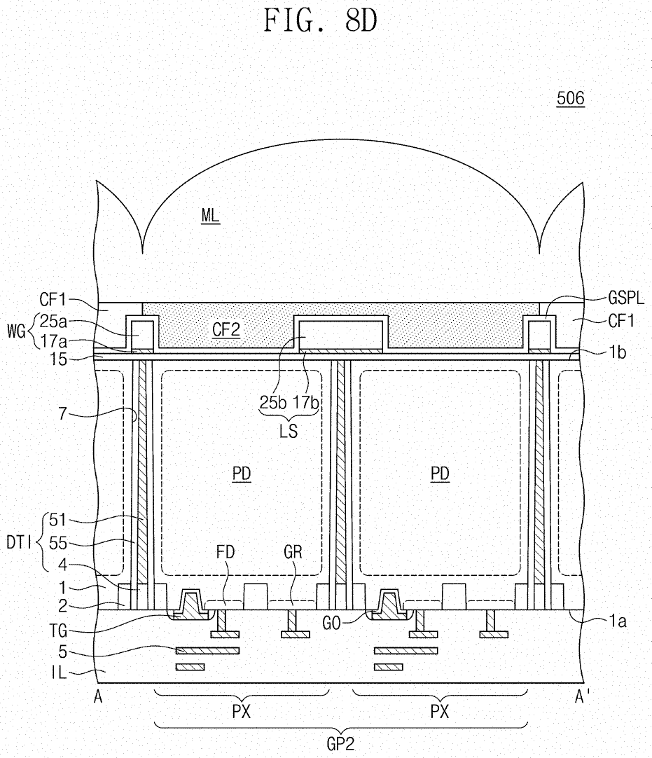

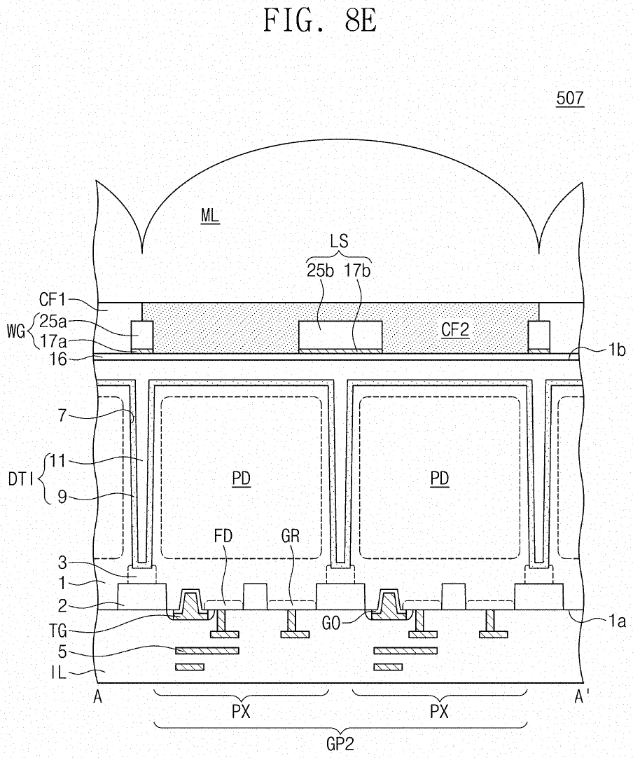

FIGS. 8A to 8E illustrate cross-sectional views taken along line A-A′ of FIG. 3A according to some embodiments of the present inventive concepts.

Referring to FIG. 8A, in an image sensor 503 according to the present embodiment, the light-shield grid WG may have a top surface at a first level LV1. The light modulator LS may have a top surface at a second level LV2. In the present embodiment, the second level LV2 may be different from the first level LV1. The second level LV2 may be higher than the first level LV1. Other configurations may be identical or similar to those discussed above with reference to FIG. 4A.

Referring to FIG. 8B, in an image sensor 504 according to the present embodiment, the light modulator LS may have an inclined sidewall. The light modulator LS may have a triangular shape when viewed in a cross-sectional view. Other configurations may be identical or similar to those discussed above with reference to FIG. 8A.

Referring to FIG. 8C, in an image sensor 505 according to the present embodiment, the light modulator LS may have an empty space CV. The empty space CV may be called an air gap. The empty space CV may expose a top surface of the second light-shield pattern 17b. The second low-refractive pattern 25b may define a top end and a lateral side of the empty space CV. Other configurations may be identical or similar to those discussed above with reference to FIG. 4A. FIG. 8C may correspond to the cross-sectional view of FIG. 6C. The phrase “air gap” will be understood to include gaps (e.g., pockets) of air or gases other than air, such as other atmospheric gases or chamber gases that may be present during manufacturing.

Referring to FIG. 8D, an image sensor 506 according to the present embodiment may include a gas penetration layer GSPL that covers the light modulator LS, the light-shield grid WG, and the fixed charge layer 15. The gas penetration layer GSPL may be formed of at least one material selected from silicon dioxide (SiO₂), hydrocarbon silicon oxide (SiOCH), and silicon carbide nitride (SiCN). The gas penetration layer GSPL may have a thickness ranging from about 0.001 nm to about 5 nm. In this case, the first low-refractive pattern 25a included in the light-shield grid WG may be an air gap, and the second low-refractive pattern 25b included in the light modulator LS may be an air gap. The fabrication of the image sensor 506 as shown in FIG. 8D may include forming the first and second low-refractive patterns 25a and 25b by using a material that can be decomposed with heat or light (e.g., ultraviolet ray) in the step of FIG. 5B, conformally forming the gas penetration layer GSPL on the first and second low-refractive patterns 25a and 25b, and then providing heat or light to the first and second low-refractive patterns 25a and 25b. In this case, the first and second low-refractive patterns 25a and 25b may be decomposed into gases having small molecular weights, and the gases may be outwardly discharged through the gas penetration layer GSPL. Therefore, the first and second low-refractive patterns 25a and 25b may be converted into air gaps.

Referring to FIG. 8E, in an image sensor 507 according to the present embodiment, the pixel isolation section DTI may be disposed in the deep trench 7. The deep trench 7 may be formed to extend from the second surface 1b toward the first surface 1a. The deep trench 7 may have a width that decreases in a direction from the second surface 1b toward the first surface 1a. The pixel isolation section DTI may include a fixed charge layer 9 that conformally covers a sidewall of the deep trench 7 and a buried dielectric layer 11 that fills the deep trench 7. The fixed charge layer 9 may have a negative fixed charge. The fixed charge layer 9 may be formed of one of metal oxide and metal fluoride that include at least one metal selected from hafnium (Hf), zirconium (Zr), aluminum (Al), tantalum (Ta), titanium (Ti), yttrium (Y), and lanthanides. For example, the fixed charge layer 9 may be a hafnium oxide layer or an aluminum oxide layer. In this case, hole accumulation may occur around the fixed charge layer 9. Therefore, dark current and white spot may be effectively reduced. In an embodiment, the buried dielectric layer 11 may be formed of a dielectric layer having excellent step coverage, for example, formed of a silicon oxide layer. Although not shown, the device isolation section DTI may have a lattice or grid shape when viewed in a plan view. The fixed charge layer 9 may extend onto and contact the second surface 1b. The buried dielectric layer 11 may also extend onto the second surface 1b.

The semiconductor substrate 1 may be provided therein with a device isolation region 3 interposed between the pixel isolation section DTI and the shallow device isolation section 2. The device isolation region 3 may be doped with impurities having a first conductivity type. A concentration of the impurities having the first conductivity type may be greater in the device isolation region 3 than in the semiconductor substrate 1.

An auxiliary dielectric layer 16 may be disposed on the buried dielectric layer 11. The auxiliary dielectric layer 16 may include one or more of an antireflection layer and a planarization layer. The auxiliary dielectric layer 16 may include one or more of a silicon nitride layer and an organic dielectric layer. Other configurations may be identical or similar to those discussed above with reference to FIG. 4A.

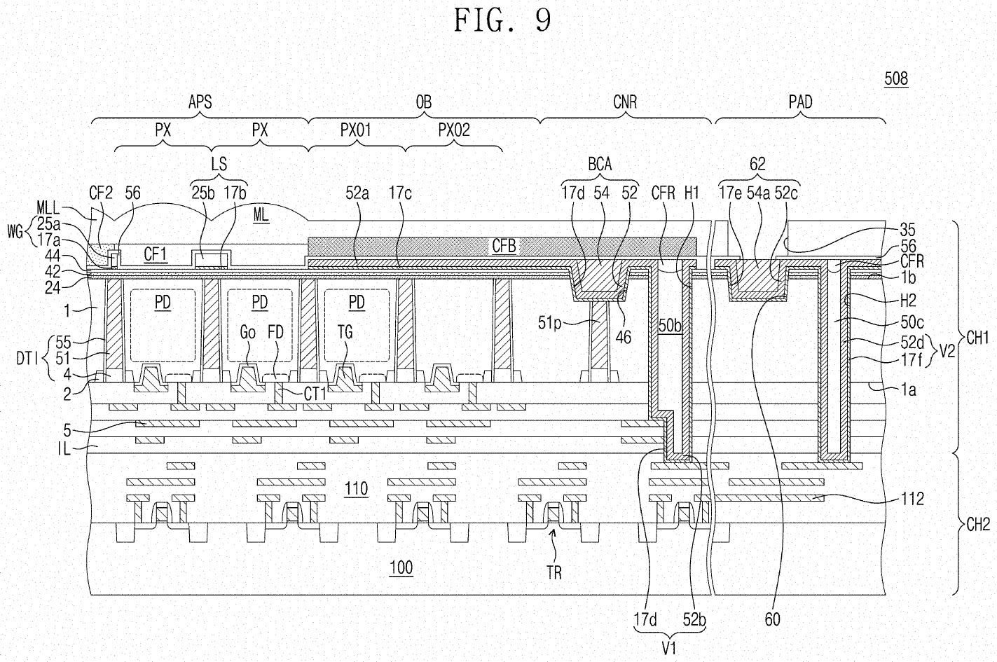

FIG. 9 illustrates a cross-sectional view showing an image sensor according to some embodiments of the present inventive concepts.

Referring to FIG. 9, an image sensor 508 according to the present embodiment may have a structure in which a first sub-chip CH1 and a second sub-chip CH2 are bonded to each other. The first sub-chip CH1 may have, for example, an image sensing function. The second sub-chip CH2 may include, for example, circuits for driving the first sub-chip CH1 or storing electrical signals generated from the first sub-chip CH1.

The second sub-chip CH2 may include a second substrate 100, a plurality of transistors TR disposed on the second substrate 100, a second interlayer dielectric layer 110 that covers the second substrate 100, and a plurality of second wiring lines 112 disposed in the second interlayer dielectric layer 110. The second interlayer dielectric layer 110 may have a single-layered or multi-layered structure formed of at least one selected from a silicon oxide layer, a silicon nitride layer, a silicon oxynitride layer, and a porous dielectric layer. The first sub-chip CH1 and the second sub-chip CH2 may be bonded to each other. Thus, the second interlayer dielectric layer 110 may be in contact with a first interlayer dielectric layer IL which will be discussed below.

The first sub-chip CH1 may include a first substrate 1 including a pad area PAD, a connection area CNR, an optical black area OB, and a pixel array area APS. The pixel array area APS may include a plurality of pixels PX. On the pixel array area APS, the first substrate 1 may be provided therein with a pixel isolation section DTI that separate the pixels PX from each other. The first substrate 1 may be provided therein with a shallow device isolation section 2 disposed adjacent to a first surface 1a thereof. The pixel isolation section DTI may penetrate the shallow device isolation section 2. On each of the pixels PX, a photoelectric conversion element PD may be disposed in the first substrate 1. On each pixel PX, a transfer gate TG may be disposed on the first surface 1a of the first substrate 1. A floating diffusion region FD may be disposed in the first substrate 1 on one side of the transfer gate TG. The first surface 1a may be covered with first interlayer dielectric layers IL. The first interlayer dielectric layers IL may be provided therein with first wiring lines 5, second wiring lines 112, and contacts CT1.

On the optical black area OB, no light may be incident on the first substrate 1. The pixel isolation section DTI may extend onto the optical black area OB to separate a first black pixel PXO1 and a second black pixel PXO2 from each other. On the first black pixel PXO1, a photoelectric conversion element PD may be disposed in the first substrate 1. On the second black pixel PXO2, no photoelectric conversion element PD may be disposed in the first substrate 1. On each of the first and second black pixels PXO1 and PXO2, a transfer gate TG and a floating diffusion region FD may be disposed. The first black pixel PXO1 may provide a first reference quantity of electric charge by detecting a quantity of electric charge possibly generated from the photoelectric conversion element PD under no light condition. The first reference quantity of electric charge may be a relative reference value when calculating a quantity of electric charge generated from the pixels PX. The second black pixel PXO2 may provide a second reference quantity of electric charge by detecting a quantity of electric charge possibly generated from a region of the substrate 1, where photoelectric conversion element PD is not formed, under no light condition. The second reference quantity of electric charge may be used as information to remove process noise.

A first fixed charge layer 24, a second fixed charge layer 42, a first protection layer 44, and a second protection layer 56 may extend onto a second surface 1b of the first substrate 1 on the optical black area OB, the connection area CNR, and the pad area PAD.

On the connection area CNR, a connection contact BCA may penetrate the first protection layer 44, the second fixed charge layer 42, and a portion of the first substrate 1, thereby being in contact with a polysilicon pattern 51 of the pixel isolation section DTI. The connection contact BCA may be positioned in a first trench 46. The connection contact BCA may include a first diffusion stop pattern 17d that conformally covers an inner sidewall and a bottom surface of the first trench 46, a first metal pattern 52 on the first diffusion stop pattern 17d, and a second metal pattern 54 that fills the first trench 46.

A portion of the first diffusion stop pattern 17d may extend onto the first protection layer 44 on the optical black area OB to provide a first optical black pattern 17c. A portion of the first metal pattern 52 may extend onto the first optical black pattern 17c on the optical black area OB to provide a second optical black pattern 52a. The second optical black pattern 52a and the connection contact BCA may be covered with the second protection layer 56. On the optical black area OB and the connection area CNR, a third optical black pattern CFB may be positioned on the second protection layer 56.

On the connection area CNR, a first via V1 may be disposed on a side of the connection contact BCA. The first via V1 may be called a back bias stack via. The first via V1 may penetrate the first protection layer 44, the second fixed charge layer 42, the first fixed charge layer 24, the first substrate 1, the first interlayer dielectric layers IL, and a portion of the second interlayer dielectric layer 110, thereby being in simultaneous contact with portions of the first wiring lines 5 and portions of the second wiring lines 112.

The first via V1 may be disposed in a first via hole H1. The first via V1 may include a first diffusion stop pattern 17d and a first via pattern 52b on the first diffusion stop pattern 17d. The first via pattern 52b may be connected to the first metal pattern 52. The connection contact BCA may be connected through the first via V1 to portions of the first wiring lines 5 and portions of the second wiring lines 112.

The first diffusion stop pattern 17d and the first via pattern 52b may each conformally cover an inner sidewall of the first via hole H1. Neither the first diffusion stop pattern 17d nor the first via pattern 52b may completely fill the first via hole H1. A first low-refractive residual layer 50b may fill the first via hole H1. A color filter residual layer CFR may be disposed on the first low-refractive residual layer 50b.

On the pad area PAD, there may be disposed an external connection pad 62 and a second via V2 that are connected to each other. The external connection pad 62 may penetrate the first protection layer 44, the second fixed charge layer 42, the first fixed charge layer 24, and a portion of the first substrate 1. The external connection pad 62 may be disposed in a fourth trench 60. The external connection pad 62 may include a second diffusion stop pattern 17e and a first pad pattern 52c that sequentially cover an inner sidewall and a bottom surface of the fourth trench 60, and may also include a second pad pattern 54a that fills the fourth trench 60.

The second via V2 may penetrate the first protection layer 44, the second fixed charge layer 42, the first fixed charge layer 24, the first substrate 1, the first interlayer dielectric layers IL, and a portion of the second interlayer dielectric layer 110, thereby being in contact with portions of the second wiring lines 112. The external connection pad 62 may be connected through the second via V2 to portions of the second wiring lines 112. The second via V2 may be disposed in a second via hole H2. The second via V2 may include a third diffusion stop pattern 17f and a second via pattern 52d that sequentially conformally cover an inner sidewall and a bottom surface of the second via hole H2. Neither the third diffusion stop pattern 17f nor the second via pattern 52d may completely fill the second via hole H2. A second low-refractive residual layer 50c may fill the second via hole H2. The color filter residual layer CFR may be disposed on the second low-refractive residual layer 50c.

The first and second light-shield patterns 17a and 17b, the first diffusion stop pattern 17d, the first optical black pattern 17c, and the first to third diffusion stop patterns 17d to 17f may have the same thickness and the same material (e.g., titanium). The first metal pattern 52, the second optical black pattern 52a, the first via pattern 52b, the first pad pattern 52c, and the second via pattern 52d may have the same thickness and the same material (e.g., tungsten). The second metal pattern 54 and the second pad pattern 54a may include the same material (e.g., aluminum).

The first and second low-refractive patterns 25a and 25b, the first low-refractive residual layer 50b, and the second low-refractive residual layer 50c may include the same material. The color filter residual layer CFR may include the same color and material as those of one of color filters CF1 and CF2.

The first light-shield pattern 17a and the first low-refractive pattern 25a may constitute a light-shield grid WG. The second light-shield pattern 17b and the second low-refractive pattern 25b may constitute a light modulator LS.

The second protection layer 56 may extend onto the pad area PAD and have an opening that exposes the second pad pattern 54a. A microlens array layer MLL including a plurality of microlens ML may extend onto the optical black area OB, the connection area CNR, and the pad area PAD. On the pad area PAD, the microlens array layer MLL may have an opening 35 that exposes the second pad pattern 54a. Other configurations may be identical or similar to those discussed with reference to FIGS. 3A and 4A.

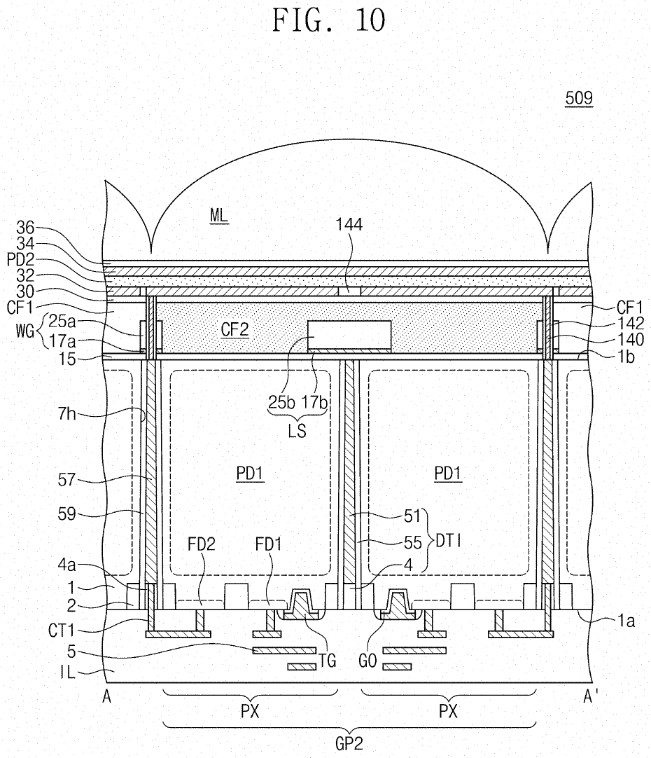

FIG. 10 illustrates a cross-sectional view taken along line A-A′ of FIG. 3A according to some embodiments of the present inventive concepts.

Referring to FIG. 10, an image sensor 509 according to the present embodiment may be configured such that a through electrode 57 may be disposed in the semiconductor substrate 1. The through electrode 57 may be insulated from the polysilicon pattern 51 of the pixel isolation section DTI. The through electrode 57 may be surrounded by a first via dielectric layer 59. A via buried dielectric pattern 4a may be disposed between the through electrode 57 and the interlayer dielectric layer IL. The through electrode 57, the first via dielectric layer 59, and the via buried dielectric pattern 4a may be disposed in a through electrode hole 7h provided in the semiconductor substrate 1. A transfer gate electrode TG may be disposed on the first surface 1a of the semiconductor substrate 1. A first floating diffusion region FD1 may be disposed in the semiconductor substrate 1 adjacent to the transfer gate electrode TG. The semiconductor substrate 1 may be provided therein with a second floating diffusion region FD2 spaced apart from the first floating diffusion region FD1 across the shallow device isolation section 2. On each of the pixels PX, a first photoelectric conversion element PD1 may be disposed in the semiconductor substrate 1. The first photoelectric conversion element PD1 may be a region doped with impurities having the second conductivity type.

A fixed charge layer 15 may be disposed on the second surface 1b of the semiconductor substrate 1. Color filters CF1 and CF2 may be disposed on the fixed charge layer 15. A light-shield grid WG may be disposed on the fixed charge layer 15 between the color filters CF1 and CF2. At a center of one of pixel groups GP1, GP2, and GP3, a light modulator LS may be disposed on the fixed charge layer 15.

A first dielectric layer 30 may be disposed on the color filters CF1 and CF2. The first dielectric layer 30 may be a silicon oxide layer or a silicon nitride layer. On each pixel PX, a pixel electrode 32 may be disposed on the first dielectric layer 30. A second dielectric layer 144 may be interposed between the pixel electrodes 32. The second dielectric layer 144 may be a silicon oxide layer or a silicon nitride layer. A second photoelectric conversion element PD2 may be disposed on the pixel electrodes 32. A common electrode 34 may be disposed on the second photoelectric conversion element PD2. A passivation layer 36 may be disposed on the common electrode 34. A microlenses ML may be disposed on the passivation layer 36.

The pixel electrode 32 and the common electrode 34 may include one or more of indium tin oxide (ITO), indium zinc oxide (IZO), zinc oxide (ZnO), and an organic transparent conductive material. The second photoelectric conversion element PD2 may be, for example, an organic photoelectric conversion layer. The second photoelectric conversion element PD2 may include a p-type organic semiconductor material and an n-type organic semiconductor material, which p-type and n-type organic semiconductor materials may form a p-n junction. In an embodiment, the second photoelectric conversion element PD2 may include quantum dots or chalcogenide.

The pixel electrode 32 may be electrically connected through a via plug 140 to the through electrode 57. The via plug 140 may include impurity-doped polysilicon, a metal nitride layer such as a titanium nitride layer, a metallic material such as tungsten, titanium, and copper, or a transparent conductive material such as ITO. The via plug 140 may penetrate the light-shield grid WG and the fixed charge layer 15 to thereby contact the through electrode 57. A second via dielectric layer 142 may cover a sidewall of the via plug 140. The through electrode 57 may be electrically connected to the second floating diffusion region FD2 through the contact CT1 and the wiring line 5. Other configurations may be identical or similar to those discussed above with reference to FIGS. 3A and 4A.

An image sensor according to the present inventive concepts may include a light modulator capable of adjusting an optical path and prevent light incidence on a polysilicon pattern included in a pixel isolation section positioned at a center of a pixel group. Accordingly, quantum efficiency may be improved to allow the image sensor to achieve a sharp image. Furthermore, an excellent autofocus function may be provided.

Although the present inventive concepts have been described in connection with some embodiments of the present inventive concepts illustrated in the accompanying drawings, it will be understood to those skilled in the art that various changes and modifications may be made without departing from the technical spirit and essential feature of the present inventive concepts. It will be apparent to those skilled in the art that various substitution, modifications, and changes may be thereto without departing from the scope and spirit of the present inventive concepts. The embodiments of FIGS. 3A to 10 may be combined with each other.

What is claimed is:

1. An image sensor comprising:
a substrate having a first surface and a second surface that are opposite to each other;
a plurality of pixels disposed at the substrate and grouped into a plurality of first pixel groups, a plurality of second pixel groups, and a plurality of third pixel groups, wherein each pixel group of the plurality of first to third pixel groups includes a first number of pixels arranged in n columns and m rows, wherein n and m represent a number of columns in each pixel group and a number of row therein, respectively, and are integers equal to or greater than 2;
a pixel isolation structure that penetrates the substrate and includes an inter-pixel group isolation and an intra-pixel group isolation, the inter-pixel group isolation separating two adjacent different pixel groups among the plurality of first to third pixel groups from each other, and the intra-pixel group isolation separating two adjacent pixels among the first number of pixels in each pixel group from each other;
a light-shield grid on the first surface and overlapping the inter-pixel group isolation of the pixel isolation structure; and
a light modulator on the first surface and overlapping the intra-pixel group isolation of the pixel isolation structure at a center of each pixel group of the plurality of first to third pixel groups,
wherein the light-shield grid has a first width in a first direction, and
wherein the light modulator has a second width, in the first direction, greater than the first width in the first direction.

2. The image sensor of claim 1, further comprising:
a color filter between the light-shield grid and the light modulator; and
a microlens on a region where the color filter, the light-shield grid, and the light modulator are disposed,
wherein a distance between a top end of the light modulator and a top end of the microlens is between about ⅓ of a curvature radius of the microlens and about ⅔ of the curvature radius of the microlens.

3. The image sensor of claim 1,
wherein the light modulator has a cross shape, a tetragonal shape, or a circular shape when viewed in a plan view.

4. The image sensor of claim 1,
wherein the light modulator has a triangular or tetragonal shape when viewed in a cross-sectional view.

5. The image sensor of claim 1,
wherein the light modulator has a through-hole therein.

6. The image sensor of claim 1,
wherein the light-shield grid has a first light-shield pattern and a first low-refractive pattern that are sequentially stacked,
wherein the light modulator has a second light-shield pattern and a second low-refractive pattern that are sequentially stacked,
wherein the first light-shield pattern and the second light-shield pattern include the same material, and
wherein the first low-refractive pattern and the second low-refractive pattern include the same dielectric material.

7. The image sensor of claim 1,
wherein a top end of the light modulator is higher than a top end of the light-shield grid.

8. The image sensor of claim 1, further comprising:
a gas penetration layer that covers the light modulator,
wherein the light modulator includes an air gap.

9. The image sensor of claim 8,
wherein the gas penetration layer includes at least one material selected from silicon dioxide (SiO₂), hydrocarbon silicon oxide (SiOCH), and silicon carbide nitride (SiCN).

10. An image sensor, comprising:
a substrate having a first surface and a second surface that are opposite to each other;
a plurality of pixels disposed at the substrate and grouped into a plurality of first pixel groups, a plurality of second pixel groups, and a plurality of third pixel groups, wherein each pixel group of the plurality of first to third pixel groups includes a first number of pixels arranged in n columns and m rows, wherein n and m represent a number of columns in each pixel group and a number of row therein, respectively, and are integers equal to or greater than 2;
a pixel isolation structure that penetrates the substrate and includes a polysilicon pattern and a dielectric layer that surrounds the polysilicon pattern, wherein the pixel isolation structure includes an inter-pixel group isolation and an intra-pixel group isolation, the inter-pixel group isolation separating two adjacent different pixel groups among the plurality of first to third pixel groups from each other, and the intra-pixel group isolation separating two adjacent pixels among the first number of pixels in each pixel group from each other;
a transfer gate on the second surface;
a floating diffusion region adjacent to the second surface and on a side of the transfer gate;
a light-shield grid on the first surface and overlapping the inter-pixel group isolation of the pixel isolation structure;
a light modulator on the first surface and overlapping the intra-pixel group isolation of the pixel isolation structure at a center of each pixel group of the plurality of first to third pixel groups;
a color filter between the light modulator and the light-shield grid; and
a microlens on a region where the color filter, the light-shield grid, and the light modulator are disposed,
wherein the light-shield grid has a first width in a first direction,
wherein the light modulator has a second width, in the first direction, greater than the first width in the first direction, and
wherein a distance between a top end of the light modulator and a top end of the microlens is between about ⅓ a curvature radius of the microlens and about ⅔ of the curvature radius of the microlens.

11. The image sensor of claim 10,
wherein the light modulator has a cross shape, a tetragonal shape, or a circular shape when viewed in a plan view.

12. The image sensor of claim 10,
wherein the light modulator has a triangular or tetragonal shape when viewed in a cross-sectional view.

13. The image sensor of claim 10,
wherein the light modulator has a through-hole therein.

14. The image sensor of claim 10,
wherein the light-shield grid has a first light-shield pattern and a first low-refractive pattern that are sequentially stacked,
wherein the light modulator has a second light-shield pattern and a second low-refractive pattern that are sequentially stacked,
wherein the first light-shield pattern and the second light-shield pattern include the same material, and
wherein the first low-refractive pattern and the second low-refractive pattern include the same dielectric material.

15. The image sensor of claim 10,
wherein the top end of the light modulator is higher than a top end of the light-shield grid.

16. The image sensor of claim 10, further comprising:
a gas penetration layer that covers the light modulator,
wherein the light modulator includes an air gap.

17. An image sensor, comprising:
a substrate having a first surface and a second surface that are opposite to each other;
a plurality of pixels disposed at the substrate and grouped into a plurality of first pixel groups, a plurality of second pixel groups, and a plurality of third pixel groups, wherein each pixel group of the plurality of first to third pixel groups includes a first number of pixels arranged in n columns and m rows, wherein n and m represent a number of columns in each pixel group and a number of row therein, respectively, and are integers equal to or greater than 2;
a pixel isolation structure that penetrates the substrate and separates the plurality of pixels from each other, the pixel isolation structure having a lattice shape when viewed in a plan view;
a light-shield grid on the first surface and overlapping the pixel isolation structure; and
a light modulator on the first surface and overlapping the pixel isolation structure at a center of each pixel group of the plurality of first to third pixel groups,
wherein the light-shield grid has a first width in a first direction,
wherein the light modulator has a second width, in the first direction, greater than the first width in the first direction,
wherein the light-shield grid has a first light-shield pattern and a first low-refractive pattern that are sequentially stacked,
wherein the light modulator has a second light-shield pattern and a second low-refractive pattern that are sequentially stacked,
wherein the first light-shield pattern and the second light-shield pattern include the same material, and
wherein the first low-refractive pattern and the second low-refractive pattern include the same dielectric material.

18. The image sensor of claim 17,
wherein the light modulator has a cross shape, a tetragonal shape, or a circular shape when viewed in a plan view.

19. The image sensor of claim 17,
wherein the light modulator has a triangular or tetragonal shape when viewed in a cross-sectional view.

20. The image sensor of claim 17,
wherein the light modulator has a through-hole therein.
